(19) United States
(12) Patent Application Publication
(10) Pub. No.: US 2021/0046561 A1
(43) Pub. Date: Feb. 18, 2021

(54) CUTTING TOOL

(71) Applicant: SUMITOMO ELECTRIC HARDMETAL CORP., Itami-shi, Hyogo (JP)

(72) Inventors: Keizo TANAKA, Itami-shi, Hyogo (JP); Shinya IMAMURA, Itami-shi, Hyogo (JP)

(73) Assignee: SUMITOMO ELECTRIC HARDMETAL CORP., Itami-shi, Hyogo (JP)

(21) Appl. No.: 16/979,985

(22) PCT Filed: Feb. 28, 2020
(86) PCT No.: PCT/JP2020/008222

§ 371 Date: Sep. 11, 2020

(30) Foreign Application Priority Data
Apr. 19, 2019 (JP) 2019-079711

(51) Int. Cl. B23C 5/16; B23B 27/14; C23C 14/06; C23C 28/04

(52) U.S. Cl. CPC B23C 5/16; B23B 27/14; C23C 14/0635; B23B 2224/32; C23C 14/0664; B23C 2224/32; C23C 28/044

(57) ABSTRACT

Provided is a cutting tool including a base material including a flank face and a coating layer that coats the flank face, the coating layer including a matrix region and metal particulates, the matrix region being made of a compound represented by (AlₓTi_{y}X_{1-x-y})CᵥO_{w}N_{1-v-w}, where X representing at least one element selected from the group consisting of chromium, silicon, niobium, tantalum, tungsten, and boron, the metal particulates containing aluminum or titanium as a constituent element, the metal particulates having particle diameters of more than or equal to 20 nm and less than or equal to 200 nm, a number of the metal particulates being more than or equal to 12 and less than or equal to 36 in a field of view of 3 μm×4 μm in a cross section parallel to a direction of a normal to an interface of the coating layer.

### TECHNICAL FIELD

The present disclosure relates to a cutting tool. The present application claims priority to Japanese Patent Application No. 2019-079711 filed on Apr. 19, 2019, the entire content of which is incorporated herein by reference.

### BACKGROUND ART

Conventionally, cutting tools made of cemented carbides or the like have been used to cut steel, castings, and the like. During cutting, a cutting edge of such a cutting tool is exposed to a harsh environment such as high temperature and high stress, which may lead to wear and chipping of the cutting edge.

Therefore, it is important to suppress wear and chipping of the cutting edge for improving the life of the cutting tool.

For the purpose of improving cutting performance of a cutting tool, coating films for coating surfaces of a base material such as a cemented carbide are under development. For example, Japanese Patent Laying-Open No. 2002-331408 (PTL 1) discloses a wear-resistant film-coated tool including a base body coated thereon with at least one layer of a hard film, that is, a hard layer having a chemical composition represented by (TiSi)(NB), the hard layer including a relatively Si-rich (TiSi)(NB) phase and a relatively Si-poor (TiSi)(NB) phase, the Si-rich (TiSi)(NB) phase being an amorphous phase.

In addition, Japanese Patent Laying-Open No. 2013-019052 (PTL 2) discloses a coating-provided item including a base material and a coating structure, the coating structure including a PVD coating region applied by physical vapor deposition, the coating region containing aluminum, yttrium, nitrogen, and at least one element selected from the group consisting of titanium, zirconium, hafnium, vanadium, niobium, tantalum, chromium, molybdenum, tungsten, and silicon, the sum of content amounts of the aluminum and the yttrium being about 3 atomic % to about 55 atomic % of the sum of the aluminum, the yttrium, and the other elements, the content amount of the yttrium being about 0.5 atomic % to about 5 atomic % of the sum of the aluminum, the yttrium, and the other elements.

### CITATION LIST

### Patent Literature

PTL 1: Japanese Patent Laying-Open No. 2002-331408

PTL 2: Japanese Patent Laying-Open No. 2013-019052

### SUMMARY OF INVENTION

A cutting tool in accordance with the present disclosure is a cutting tool including:

a base material including a flank face; and

a coating layer that coats the flank face,

the coating layer including a matrix region and metal particulates,

the matrix region being made of a compound represented by (AlₓTi_{y}X_{1-x-y})CᵥO_{w}N_{1-v-w}, where

x being more than 0.5 and less than or equal to 0.7,

y being more than or equal to 0.3 and less than 0.5,

1-x-y being more than or equal to 0 and less than or equal to 0.1,

v being more than or equal to 0 and less than or equal to 1,

w being more than or equal to 0 and less than or equal to 1,

1-v-w being more than or equal to 0 and less than or equal to 1,

X representing at least one element selected from the group consisting of chromium, silicon, niobium, tantalum, tungsten, and boron,

the metal particulates containing aluminum or titanium as a constituent element,

the metal particulates having particle diameters of more than or equal to 20 nm and less than or equal to 200 nm,

a number of the metal particulates being more than or equal to 12 and less than or equal to 36 in a field of view of 3 μm×4 μm in a cross section parallel to a direction of a normal to an interface of the coating layer.

### BRIEF DESCRIPTION OF DRAWINGS

FIG. 1 is a perspective view illustrating one aspect of a base material of a cutting tool.

FIG. 2 is a schematic cross sectional view of a cutting tool in one aspect of the present embodiment.

FIG. 3A is a photograph showing an example of an electron beam diffraction pattern in a coating layer in accordance with the present embodiment.

FIG. 3B is a photograph showing another example of the electron beam diffraction pattern in the coating layer in accordance with the present embodiment.

FIG. 4A is a transmission electron microscope photograph of a cross section of the coating layer in accordance with the present embodiment.

FIG. 4B is an enlarged photograph of a metal particulate portion in the transmission electron microscope of the cross section of the coating layer in accordance with the present embodiment.

### DETAILED DESCRIPTION

### Problem to be Solved by the Present Disclosure

However, the wear-resistant film-coated tool disclosed in PTL 1 has a low hardness because the film includes an amorphous layer. Accordingly, when the tool is applied to highly efficient (fast feeding speed) cutting, further improvement in performance (for example, crater wear resistance, wear resistance, and the like) is required.

The present disclosure has been made in view of the aforementioned circumstances, and an object thereof is to provide a cutting tool that is excellent in flank face wear resistance.

### Advantageous Effect of the Present Disclosure

According to the above, a cutting tool that is excellent in flank face wear resistance can be provided.

### Description of Embodiment of the Present Disclosure

First, aspects of the present disclosure will be described in list form.

[1] A cutting tool in accordance with the present disclosure is a cutting tool including:

a base material including a flank face; and

a coating layer that coats the flank face,

the coating layer including a matrix region and metal particulates,

the matrix region being made of a compound represented by (AlₓTi_{y}X_{1-x-y})CᵥO_{w}N_{1-v-w}, where

x being more than 0.5 and less than or equal to 0.7,

y being more than or equal to 0.3 and less than 0.5,

1-x-y being more than or equal to 0 and less than or equal to 0.1,

v being more than or equal to 0 and less than or equal to 1,

w being more than or equal to 0 and less than or equal to 1,

1-v-w being more than or equal to 0 and less than or equal to 1,

X representing at least one element selected from the group consisting of chromium, silicon, niobium, tantalum, tungsten, and boron,

the metal particulates containing aluminum or titanium as a constituent element,

the metal particulates having particle diameters of more than or equal to 20 nm and less than or equal to 200 nm,

a number of the metal particulates being more than or equal to 12 and less than or equal to 36 in a field of view of 3 μm×4 μm in a cross section parallel to a direction of a normal to an interface of the coating layer.

By including a configuration as described above, the cutting tool can have an excellent flank face wear resistance.

[2] The coating layer further contains argon, and the argon has a content ratio of more than 0 at % and less than or equal to 3 at % in the coating layer. By such a definition, the cutting tool can have a further excellent flank face wear resistance.

[3] The X includes boron. By such a definition, the cutting tool can have a further excellent flank face wear resistance.

[4] The coating layer has a thickness of more than or equal to 3 μm and less than or equal to 20 μm. By such a definition, the cutting tool can have a further excellent flank face wear resistance.

### Details of Embodiment of the Present Disclosure

One embodiment of the present disclosure (hereinafter referred to as the “present embodiment”) will be described below, although the present embodiment is not limited thereto. In the present specification, an expression in the form of “A to Z” means lower and upper limits of a range (that is, more than or equal to A and less than or equal to Z), and when A is not accompanied by any unit and Z is alone accompanied by a unit, A has the same unit as Z. Further, in the present specification, when a compound is represented by a chemical formula in which composition ratios of constituent elements are unspecified, such as “TiC”, for example, the chemical formula shall include any conventionally known composition ratio (element ratio). On this occasion, the above chemical formula shall include not only a stoichiometric composition but also a non-stoichiometric composition. For example, the chemical formula “TiC” includes not only a stoichiometric composition “Ti₁C₁” but also a non-stoichiometric composition such as “Ti₁C_{0.8}”, for example. The same applies to the description of compounds other than “TiC”.

### Surface-Coated Cutting Tool

A cutting tool in accordance with the present disclosure is a cutting tool including:

a base material including a flank face; and

a coating layer that coats the flank face,

the coating layer including a matrix region and metal particulates,

the matrix region being made of a compound represented by (AlₓTi_{y}X_{1-x-y})CᵥO_{w}N_{1-v-w}, where

x being more than 0.5 and less than or equal to 0.7,

y being more than or equal to 0.3 and less than 0.5,

1-x-y being more than or equal to 0 and less than or equal to 0.1,

v being more than or equal to 0 and less than or equal to 1,

w being more than or equal to 0 and less than or equal to 1,

1-v-w being more than or equal to 0 and less than or equal to 1,

X representing at least one element selected from the group consisting of chromium, silicon, niobium, tantalum, tungsten, and boron,

the metal particulates containing aluminum or titanium as a constituent element,

the metal particulates having particle diameters of more than or equal to 20 nm and less than or equal to 200 nm,

a number of the metal particulates being more than or equal to 12 and less than or equal to 36 in a field of view of 3 μm×4 μm in a cross section parallel to a direction of a normal to an interface of the coating layer.

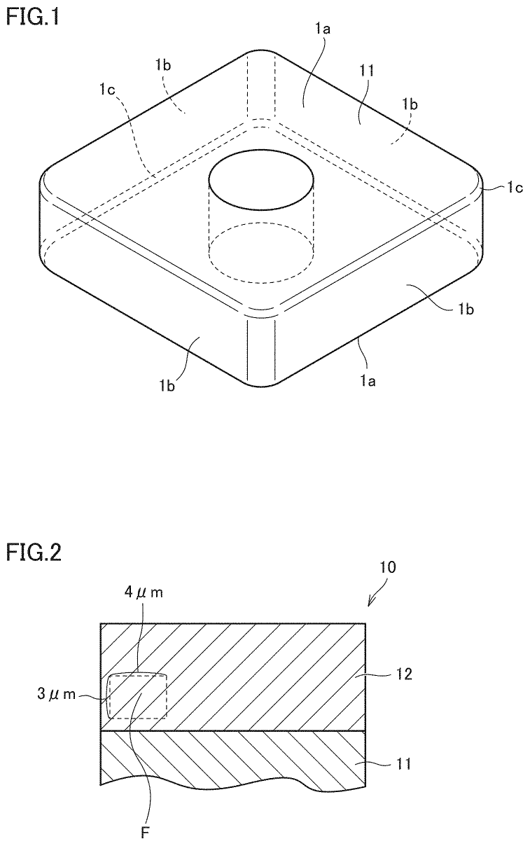

A surface-coated cutting tool 10 of the present embodiment includes a base material 11 including a flank face 1b, and a coating layer 12 that coats flank face 1b (hereinafter may be simply referred to as a “cutting tool”) (FIGS. 1 and 2). In addition to the coating layer, the cutting tool may further include an underlying layer provided between the base material and the coating layer. The cutting tool may further include an intermediate layer provided between the underlying layer and the coating layer. The cutting tool may further include an outermost surface layer provided on the coating layer. Other layers such as the underlying layer, the intermediate layer, and the outermost surface layer will be described later.

It should be noted that the above layers provided on the base material may be collectively referred to as a “coating film”. That is, the cutting tool includes a coating film that coats the flank face, and the coating film includes the coating layer. In addition, the coating film may further include the underlying layer, the intermediate layer, or the outermost surface layer.

The cutting tool may be a drill, an end mill, a cutting edge-replaceable cutting tip for drills, a cutting edge-replaceable cutting tip for end mills, a cutting edge-replaceable cutting tip for milling, a cutting edge-replaceable cutting tip for turning, a metal saw, a gear cutting tool, a reamer, a tap, or the like, for example.

### Base Material

As the base material of the present embodiment, any material can be used as long as it is conventionally known as a base material of this type. For example, the base material preferably includes one selected from the group consisting of cemented carbides (for example, a tungsten carbide (WC)-based cemented carbide, a cemented carbide containing Co in addition to WC, a cemented carbide with a carbonitride of Cr, Ti, Ta, Nb, or the like being added thereto in addition to WC, and the like), cermets (composed mainly of TiC, TiN, TiCN, and the like), a high-speed steel, ceramics (titanium carbide, silicon carbide, silicon nitride, aluminum nitride, aluminum oxide, and the like), a cubic boron nitride sintered body (cBN sintered body), and a diamond sintered body.

Of these various base materials, a cemented carbide (in particular, a WC-based cemented carbide) or a cermet (in particular, a TiCN-based cermet) is particularly preferably selected, because these base materials are particularly excellent in balance between hardness and strength at high temperature, and have excellent characteristics as the base material of the cutting tool for the use described above.

When a cemented carbide is used as the base material, the effect of the present embodiment is exhibited even if such a cemented carbide includes free carbon or an abnormal phase called η phase in the structure. It should be noted that the base material used in the present embodiment may have a reformed surface. For example, when the base material is a cemented carbide, a β-free layer may be formed on a surface thereof, and when the base material is a cBN sintered body, a surface-hardened layer may be formed. The effect of the present embodiment is exhibited even if the surface is reformed as described above.

FIG. 1 is a perspective view illustrating one aspect of the base material of the cutting tool. The cutting tool having such a shape is used as a cutting edge-replaceable cutting tip for turning.

Base material 11 shown in FIG. 1 has surfaces including an upper surface, a lower surface, and four side surfaces, and as a whole has the shape of a square prism which is slightly thin in an upward/downward direction. In addition, a through hole penetrating the upper and lower surfaces is formed in base material 11, and at each of boundary portions of the four side surfaces, adjacent side surfaces are connected along an arc surface.

Generally, in base material 11, the upper surface and the lower surface each serve as a rake face 1a, the four side surfaces (and the arc surfaces which each connect the side surfaces with each other) each serve as flank face 1b, and an arc surface which connects rake face 1a and flank face 1b serves as a cutting edge portion 1c. The “rake face” means a face which rakes out chips scraped from a workpiece. The “flank face” means a face having a portion which comes into contact with the workpiece. The cutting edge portion is included in a portion constituting a cutting edge of the cutting tool.

When the cutting tool is a cutting edge-replaceable cutting tip, base material 11 may have a shape having a chip breaker, or may have a shape not having a chip breaker. The shape of cutting edge portion 1c includes any of a sharp edge (a ridge at which a rake face intersects with a flank face), a honed shape (a shape obtained by rounding a sharp edge), a negative land (a beveled shape), and a combination of a honed shape and a negative land.

Although the shape of base material 11 and the name of each portion thereof are described above using FIG. 1, in the cutting tool in accordance with the present embodiment, the same terms as those described above will be used for the shape and the name of each portion corresponding to base material 11. That is, the cutting tool has a rake face, a flank face, and a cutting edge portion which connects the rake face and the flank face.

### Coating Film

The coating film in accordance with the present embodiment includes a coating layer. The “coating film” coats at least a portion of the base material (for example, a portion of the flank face) to have a function of improving various characteristics such as chipping resistance and flank face wear resistance in the cutting tool. The coating film preferably coats the entire surfaces of the base material. However, even if a portion of the base material is not coated with the coating film or the configuration of the coating film is partially different, such a case does not depart from the scope of the present embodiment.

The coating film has a thickness of preferably more than or equal to 3 μm and less than or equal to 20 μm, and more preferably more than or equal to 3 μm and less than or equal to 12 μm. Here, the thickness of the coating film means the sum of thicknesses of layers constituting the coating film. Examples of the “layers constituting the coating film” include the coating layer, and other layers such as the underlying layer, the intermediate layer, and the outermost surface layer described above. The thickness of the coating film can be determined for example by measuring thicknesses at 10 arbitrary points in a cross section sample parallel to a direction of a normal to a surface of the base material using a transmission electron microscope (TEM), and calculating an average value of the thicknesses measured at the 10 points. The measurement magnification on this occasion is 10000 times, for example. Examples of the cross section sample include a sample of a cross section of the cutting tool sliced using an ion slicer apparatus. The same applies to the measurement of the thicknesses of the coating layer and the underlying layer, the intermediate layer, and the outermost surface layer described above. Examples of the transmission electron microscope include JEM-2100F (trade name) manufactured by JEOL Ltd.

(Coating Layer)

The coating layer in accordance with the present embodiment includes a matrix region and metal particulates. The coating layer may be provided directly on the base material, or may be provided on the base material with another layer such as the underlying layer being interposed therebetween, as long as the effect exhibited by the cutting tool in accordance with the present embodiment is not impaired. The coating layer may be provided thereon with another layer such as the outermost surface layer. In addition, the coating layer may be provided at an outermost surface of the coating film. Although the coating layer only has to coat the flank face of the base material, the coating layer may coat the rake face of the base material. The coating layer preferably coats the entire surfaces of the base material. However, even if a portion of the base material is not coated with the coating layer, such a case does not depart from the scope of the present embodiment.

The coating layer has a thickness of preferably more than or equal to 3 μm and less than or equal to 20 μm, more preferably more than or equal to 3 μm and less than or equal to 12 μm, and further preferably more than or equal to 3 μm and less than or equal to 8 μm. Thereby, the cutting tool can have a further excellent flank face wear resistance. The thickness can be measured for example by observing a cross section of the cutting tool as described above, using a transmission electron microscope, with a magnification of 10000 times.

(Matrix Region)

The “matrix region” is a region serving as a matrix of the coating layer, and means a region other than the metal particulates (when the coating layer contains Ar (argon) described later, the matrix region means a region other than the metal particulates and Ar). In other words, the matrix region is a region arranged to surround each of the metal particulates. In another aspect of the present embodiment, it can also be understood that most of the matrix region is a region arranged to surround each of the metal particulates. In addition, it can also be understood that most of the matrix region is arranged between the metal particulates.

The matrix region is made of a compound represented by (AlₓTi_{y}X_{1-x-y})CᵥO_{w}N_{1-v-w} (where 0.5<x≤0.7, 0.3≤y<0.5, 0≤1-x-y≤0.1, 0≤v≤1, 0≤w≤1, 0≤1-v-w—1). By setting the composition of the matrix region as described above, a fine polycrystalline structure described later is formed, as the metal particulates described later are dispersed in the matrix region. As a result, a cutting tool that is excellent in flank face wear resistance is obtained. Here, X represents at least one element selected from the group consisting of Cr (chromium), Si (silicon), Nb (niobium), Ta (tantalum), W (tungsten), and B (boron).

It should be noted that, although boron is generally considered as a semi-metal exhibiting properties intermediate between a metal element and a non-metal element, boron shall be included in the range of metal elements in the present embodiment, based on the premise that an element having a free electron is a metal.

In (AlₓTi_{y}X_{1-x-y})CᵥO_{w}N_{1-v-w}, x is more than 0.5 and less than or equal to 0.7, and is preferably more than or equal to 0.55 and less than or equal to 0.65. The x can be determined by analyzing the entire matrix region of the cross section sample described above using TEM-accompanying energy dispersive X-ray spectroscopy (TEM-EDX). The observation magnification on this occasion is 20000 times, for example. Specifically, measurement is performed at each of 10 arbitrary points in the matrix region of the cross section sample to obtain values of the x, and an average value of the values obtained at the 10 points is determined as x in the matrix region. Here, the “10 arbitrary points” shall be selected from mutually different crystal grains in the matrix region. The same applies to the determination of y, v, and w described later. Examples of an apparatus for the EDX include JED-2300 (trade name) manufactured by JEOL Ltd.

In (AlₓTi_{y}X_{1-x-y})CᵥO_{w}N_{1-v-w}, y is more than or equal to 0.3 and less than 0.5, and is preferably more than or equal to 0.3 and less than or equal to 0.4.

In (AlₓTi_{y}X_{1-x-y})CᵥO_{w}N_{1-v-w}, 1-x-y is more than or equal to 0 and less than or equal to 0.1, and is preferably more than or equal to 0.03 and less than or equal to 0.1.

In (AlₓTi_{y}X_{1-x-y})CᵥO_{w}N_{1-v-w}, v is more than or equal to 0 and less than or equal to 1, and is preferably more than or equal to 0 and less than or equal to 0.2.

In (AlₓTi_{y}X_{1-x-y})CᵥO_{w}N_{1-v-w}, w is more than or equal to 0 and less than or equal to 1, and is preferably more than or equal to 0 and less than or equal to 0.2.

In (AlₓTi_{y}X_{1-x-y})CᵥO_{w}N_{1-v-w}, 1-v-w is more than or equal to 0 and less than or equal to 1, and is preferably more than or equal to 0.6 and less than or equal to 0.9.

In (AlₓTi_{y}X_{1-x-y})CᵥO_{w}N_{1-v-w}, X may include two or more elements selected from the group consisting of Cr, Si, Nb, Ta, W, and B. In this case, the value of 1-x-y described above means the sum of values of the two or more elements.

In an aspect of the present embodiment, the X preferably includes B (boron). Thereby, the cutting tool can have a further excellent flank face wear resistance.

Examples of the compound represented by (AlₓTi_{y}X_{1-x-y})CᵥO_{w}N_{1-v-w} include AlTiN, AlTiBN, AlTiBCN, AlTiBON, AlTiBCON, and the like (note that subscripts indicated by x, y, v, and w in the specific compounds are omitted).

(Metal Particulates)

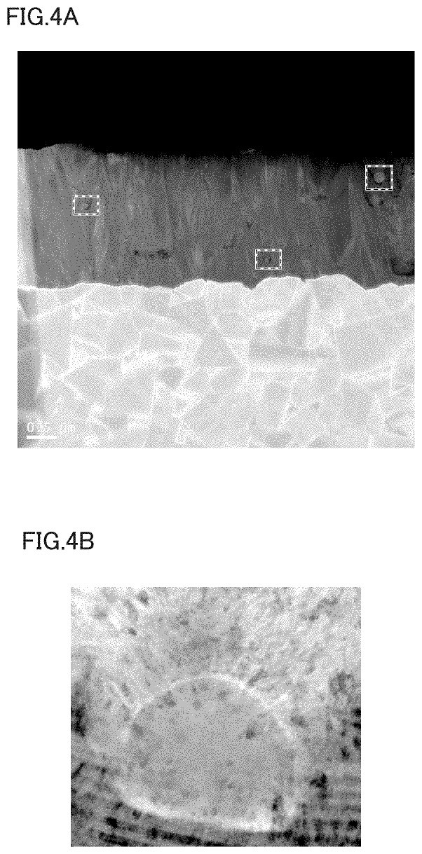

It can be understood that the metal particulates in accordance with the present embodiment exist in a state where they are dispersed in the matrix region (for example, portions surrounded by broken lines in FIG. 4A). It should be noted that the “state where they are dispersed” described above does not exclude a state where the metal particulates are in contact with each other. That is, the metal particulates may be in contact with each other, or may be separated from each other.

The present inventors have found for the first time that, in the matrix region in which the metal particulates are dispersed, a structure made of a polycrystal having a grain diameter smaller than that of the surroundings is formed above the metal particulates (opposite to the base material) (FIGS. 4A and 4B). The existence of a structure made of such a polycrystal (hereinafter may be referred to as a “fine polycrystalline structure”) improves the toughness of the coating layer. Accordingly, the cutting tool has an excellent flank face wear resistance.

The metal particulates contain Al (aluminum) or Ti (titanium) as a constituent element. Specific examples include metal particulates made of Al, metal particulates made of Ti, metal particulates made of an alloy of Al and Ti, and the like. The composition of the metal particulates can be determined by analyzing the metal particulates of the cross section sample using TEM-EDX, in the same way as described above.

In addition, oxide, carbide, nitride, or the like may be formed on surfaces of the metal particulates, as long as the effect exhibited by the present disclosure is not impaired.

The metal particulates have particle diameters of more than or equal to 20 nm and less than or equal to 200 nm, preferably more than or equal to 20 nm and less than or equal to 160 nm, and more preferably more than or equal to 20 nm and less than or equal to 120 nm. When the metal particulates have particle diameters of less than 20 nm, the fine polycrystalline structure is less likely to be formed. In addition, when the metal particulates have particle diameters of more than 200 nm, the toughness of the coating layer is more likely to be decreased. The particle diameters of the metal particulates can be determined using a TEM. Specifically, the particle diameters of the metal particulates are determined by the following procedure. First, the cross section sample described above is observed with the TEM to obtain an observation image. The observation magnification on this occasion is 100000 times, for example. The metal particulates and the matrix region have different densities. Accordingly, a clear difference in contrast appears on the obtained observation image, and thus the metal particulates and the matrix region can be clearly distinguished. In the obtained observation image, the area of a cross section of each metal particulate is calculated. The diameter of a circle having an area equal to the calculated area is calculated. The diameter of the circle calculated as described above is defined as the particle diameter of the metal particulate.

It should be noted that, although metal particles having particle diameters of more than or equal to 20 nm and less than or equal to 200 nm are defined as the “metal particulates” in the present embodiment, the definition does not exclude a case where metal particles having particle diameters out of the range described above are contained in the coating layer. That is, the coating layer may include metal particles having particle diameters of less than 20 nm, or metal particles having particle diameters of more than 200 nm, as long as the effect exhibited by the present disclosure is not impaired.

The number of the metal particulates is more than or equal to 12 and less than or equal to 36 in a field of view of 3 μm×4 μm (for example, a field of view F in FIG. 2) in a cross section parallel to a direction of a normal to an interface of the coating layer. Here, the “interface of the coating layer” described above means an interface closest to the base material, of two interfaces perpendicular to a thickness direction of the coating layer. For example, when the coating layer is arranged directly on the base material, a boundary surface between the base material and the coating layer serves as the “interface of the coating layer” described above. When another layer such as the underlying layer described later is arranged on the base material, and the coating layer is arranged directly on the other layer, a boundary surface between the other layer and the coating layer serves as the “interface of the coating layer” described above.

As a method of counting the number of the metal particulates, specifically, first, a plurality of arbitrary fields of view in the cross section sample described above are observed with the TEM to count the number of the metal particulates for each field of view. An average of the numbers of the metal particulates counted for the respective fields of view is calculated to determine the number of the metal particulates. The magnification on this occasion is 50000 times, for example. In addition, the number of the fields of view to be measured is at least 3. It should be noted that a metal particulate which is partially out of a field of view for measurement is also counted as one metal particulate.

(Fine Polycrystalline Structure)

In an aspect of the present embodiment, it can be understood that the matrix region includes a fine polycrystalline structure adjacent to the metal particulates. The fine polycrystalline structure can be distinguished from a structure other than the fine polycrystalline structure in the matrix region, by analyzing an image of the cross section sample obtained with the TEM. The composition of the fine polycrystalline structure can be represented by the same composition as that of a portion other than that in the matrix region, that is, (AlₓTi_{y}X_{1-x-y})CᵥO_{w}N_{1-v-w}.

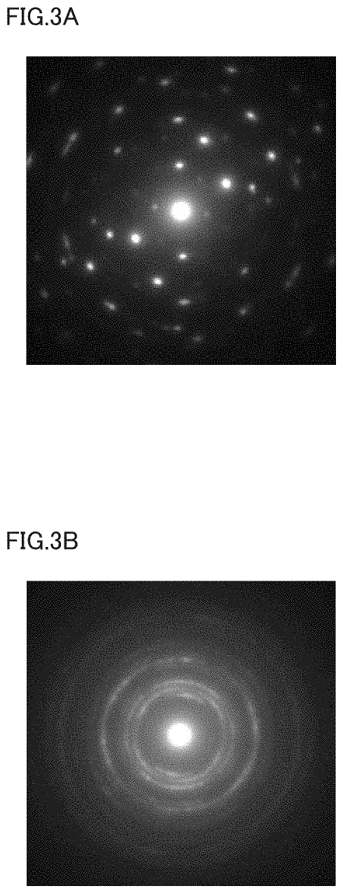

In addition, grain diameters of crystal grains constituting the fine polycrystalline structure can be determined by the analysis using an electron beam diffraction method. Specifically, the analysis is performed by the following procedure. First, electron beam diffraction measurement is performed on a portion above the metal particulates in the cross section sample described above. On this occasion, the measurement is performed with the beam diameter of an emitted electron beam being changed from 2 nm to 30 nm. When the beam diameter of the electron beam is smaller than the grain diameters of the crystal grains constituting the fine polycrystalline structure, discrete and large diffraction spots are observed in an electron beam diffraction image (for example, FIG. 3A). On the other hand, when the beam diameter of the electron beam is larger than the grain diameters of the crystal grains constituting the fine polycrystalline structure, a continuous ring pattern is observed in the electron beam diffraction image (for example, FIG. 3B). That is, the beam diameter of the electron beam when the observed pattern changes from diffraction spots to a continuous ring pattern in the electron beam diffraction image corresponds to the grain diameters of the crystal grains constituting the polycrystalline structure. In the present embodiment, the grain diameters of the crystal grains constituting the fine polycrystalline structure may be more than or equal to 2 nm and less than or equal to 20 nm, or more than or equal to 2 nm and less than or equal to 10 nm, for example.

(Ar)

Preferably, the coating layer further contains Ar (argon), and the Ar has a content ratio of more than 0 at % and less than or equal to 3 at % in the coating layer. Thereby, the cutting tool can have a further excellent flank face wear resistance. The content ratio of the Ar in the coating layer can be determined by analyzing the entire matrix region of the cross section sample described above using TEM-EDX.

(Other Layers)

The coating film may further include other layers, as long as the effect of the present embodiment is not impaired. Examples of the other layers include an underlying layer provided between the base material and the coating layer, an intermediate layer provided between the underlying layer and the coating layer, an outermost surface layer provided on the coating layer, and the like. The underlying layer may be a layer made of a compound represented by TiWCN, for example. The intermediate layer may be a layer made of a compound represented by TiN, for example. The outermost surface layer may be a layer made of a compound represented by AlTiCN, for example. The thicknesses of the other layers are not particularly limited as long as the effect of the present embodiment is not impaired, and are more than or equal to 0.1 μm and less than or equal to 2 μm, for example.

### Method for Manufacturing Surface-Coated Cutting Tool

A method for manufacturing the cutting tool in accordance with the present embodiment includes:

a step of preparing the base material (hereinafter may be referred to as a “first step”); and

a step of forming the coating layer on the flank face in the base material using a physical vapor deposition method (hereinafter may be referred to as a “second step”),

the step of forming the coating layer including intermittently supplying Ar gas.

The physical vapor deposition method is a vapor deposition method of vaporizing a source material (also referred to as an “evaporation source” or a “target”) utilizing a physical action, and depositing the vaporized source material on a base material or the like. In particular, the physical vapor deposition method used in the present embodiment is a cathodic arc ion plating method.

In the cathodic arc ion plating method, the base material in placed within an apparatus and a target is also placed therein as a cathode, and then a high current is applied to the target to generate an arc discharge. Thereby, atoms constituting the target are evaporated and ionized, and are deposited on the base material to which a negative bias voltage is applied, to form a coating film.

### First Step: Step of Preparing Base Material

In the first step, the base material is prepared. For example, a cemented carbide base material is prepared as the base material. The cemented carbide base material may be a commercially available base material, or may be manufactured by a common powder metallurgy method. When the cemented carbide base material is manufactured by a common powder metallurgy method, for example, WC powder, Co powder, and the like are mixed by a ball mill or the like to obtain mixed powder. The mixed powder is dried, and thereafter is molded into a predetermined shape to obtain a molded body. Further, the molded body is sintered to obtain a WC-Co-based cemented carbide (sintered body). Subsequently, the sintered body is subjected to predetermined cutting edge processing such as honing, and thereby a base material made of a WC—Co-based cemented carbide can be manufactured. In the first step, any base material other than that described above can be prepared, as long as it is conventionally known as a base material of this type.

### Second Step: Step of Forming Coating Layer

In the second step, the coating layer is formed on the flank face in the base material. As a method therefor, various methods can be used depending on the composition of the coating layer to be formed. Examples of the method can include a method of using a target made of an alloy with particle diameters of Ti, Al, and the like being changed respectively, a method of using a plurality of targets having respectively different compositions, a method of using a pulse voltage as a bias voltage to be applied during film formation, a method of changing a gas flow rate during film formation, a method of adjusting the rotation speed of a base material holder that holds the base material in a film formation apparatus, and the like.

For example, the second step can be performed as follows. First, as the base material, a tip having an arbitrary shape is placed within a chamber of the film formation apparatus. For example, the base material is attached to an outer surface of the base material holder on a rotary table which is rotatably provided at the center within the chamber of the film formation apparatus. A bias power supply is attached to the base material holder. While the base material is rotated at the center within the chamber, nitrogen gas or the like is introduced as a reaction gas. Further, while the temperature of the base material is maintained at 400 to 700° C., the pressure of the reaction gas is maintained at 3 to 6 Pa, and the voltage of the bias power supply is maintained in the range of −30 to −800 V, an arc current of 100 to 200 A is supplied to an evaporation source for forming the coating layer. Thereby, metal ions are produced from the evaporation source for forming the coating layer, and after a lapse of a predetermined time, supply of the arc current is stopped, and the coating layer is formed on a surface of the flank face in the base material. On this occasion, the thickness of the coating layer is adjusted to be within a predetermined range, by adjusting a film formation time. In the second step, the coating layer may be formed on a surface of the base material other than the flank face (for example, on a surface of the rake face), in addition to the flank face described above.

In the second step, the source material for the coating layer contains Al and Ti. The source material for the coating layer may further contain at least one selected from the group consisting of Cr, Si, Nb, Ta, W, and B. In an aspect of the present embodiment, the source material for the coating layer preferably further contains B.

When the entire source material for the coating layer is represented as 1, the content ratio (atomic ratio) of the Al is preferably more than 0.5 and less than or equal to 0.7, and more preferably more than or equal to 0.55 and less than or equal to 0.65. Here, the content ratio of the Al with respect to the entire source material generally corresponds to the composition ratio of the Al in the matrix region. The same applies to other elements such as Ti, B, and the like described later.

When the entire source material for the coating layer is represented as 1, the content ratio (atomic ratio) of the Ti is preferably more than or equal to 0.3 and less than 0.5, and more preferably more than or equal to 0.3 and less than or equal to 0.4.

In a case where boron is contained in the source material for the coating layer, when the entire source material for the coating layer is represented as 1, the content ratio (atomic ratio) of the boron is preferably more than or equal to 0.03 and less than or equal to 0.15, and more preferably more than or equal to 0.05 and less than or equal to 0.1.

In the present embodiment, the step of forming the coating layer includes intermittently supplying Ar gas. Thereby, metal particulates are produced in the course of forming the coating layer. Examples of a method of intermittently supplying Ar gas include a method of intermittently supplying Ar gas at a partial pressure of 1 Pa, with an interval of more than or equal to 5 minutes and less than or equal to 30 minutes. On this occasion, a single supply is performed for more than or equal to 10 seconds and less than or equal to 30 seconds.

In the present embodiment, the reaction gas described above is not particularly limited as long as it is a reaction gas commonly used in the physical vapor deposition method. The reaction gas can be selected as appropriate according to the composition of the coating layer. Examples of the reaction gas include nitrogen gas, hydrocarbon gas such as acetylene gas, oxygen gas, and the like.

After the coating layer is formed, compressive residual stress may be imparted to the coating film to improve toughness. The compressive residual stress can be imparted by blasting, brushing, barrel processing, ion implantation, or the like, for example.

### Other Steps

In the manufacturing method in accordance with the present embodiment, in addition to the steps described above, an ion bombardment treatment step of performing ion bombardment treatment on a surface of the base material, an underlying layer coating step of forming an underlying layer between the base material and the coating layer, an intermediate layer coating step of forming an intermediate layer between the underlying layer and the coating layer, an outermost surface layer coating step of forming an outermost surface layer on the coating layer, a step of performing surface treatment, and the like may be performed as appropriate between the first step and the second step. When other layers such as the underlying layer, the intermediate layer, and the outermost layer described above are formed, the other layers may be formed by a conventional method. Specifically, for example, the other layers may be formed by the PVD method described above. Examples of the step of performing surface treatment include performing surface treatment using a medium having a stress imparting elastic material carrying diamond powder. Examples of an apparatus for performing the surface treatment include Sirius Z manufactured by Fuji Manufacturing Co., Ltd.

The above description includes features noted below.

(Note 1)

A surface-coated cutting tool comprising:

a base material including a flank face; and

a coating layer that coats the flank face,

the coating layer including a matrix region and metal particulates,

the matrix region being made of a compound represented by (AlₓTi_{y}X_{1-x-y})CᵥO_{w}N_{1-v-w}, (where 0.5<x≤0.7, 0.3≤y<0.5, 0≤1-x-y≤0.1, 0≤v≤1, 0≤w≤1, 0≤1-v-w≤1, and X represents at least one element selected from the group consisting of Cr, Si, Nb, Ta, W, and B),

the metal particulates containing Al or Ti as a constituent element,

the metal particulates having particle diameters of more than or equal to 20 nm and less than or equal to 200 nm,

a number of the metal particulates being more than or equal to 12 and less than or equal to 36 in a field of view of 3μm×4 μm in a cross section parallel to a direction of a normal to an interface of the coating layer.

(Note 2)

The surface-coated cutting tool according to note 1, wherein

the coating layer further contains Ar, and

the Ar has a content ratio of more than 0 a t% and less than or equal to 3 at % in the coating layer.

(Note 3)

The surface-coated cutting tool according to note 1 or 2, wherein the X includes B.

(Note 4)

The surface-coated cutting tool according to any one of notes 1 to 3, wherein the coating layer has a thickness of more than or equal to 1 μm and less than or equal to 20 μm.

### EXAMPLES

In the following, the present invention will be described in detail with reference to examples, although the present invention is not limited thereto.

### Fabrication of Cutting Tool

### Preparation of Base Material

First, as a base material on which a coating film was to be formed, a surface-coated cemented carbide tip for turning (DCGT11T3-2R-FY, a cemented carbide equivalent to K20 according to the JIS standard) was prepared (the first step: the step of preparing the base material).

### Ion Bombardment Treatment

Prior to the fabrication of a coating film described later, ion bombardment treatment was performed on a surface of the base material by the following procedure. First, the base material was set in an arc ion plating apparatus. Then, the ion bombardment treatment was performed under the following conditions.

Gas composition: Ar (100%)

Gas pressure: 0.5 Pa

Bias voltage: 600 V (direct current (DC) power supply)

Treatment time: 60 minutes

### Fabrication of Coating Film

On the surface of the base material subjected to the ion bombardment treatment (on the surface including a flank face), each coating layer shown in Tables 1-1 and 1-2 was formed to fabricate a coating film. In the following, a method for fabricating each coating layer will be described.

(Fabrication of Coating Layer)

In samples Nos. 1 to 9 and 13 to 27, nitrogen was introduced as a reaction gas while the base material was rotated at the center within the chamber. In sample No. 10, nitrogen gas and acetylene gas were introduced as reaction gases. In sample No. 11, nitrogen gas and oxygen gas were introduced as reaction gases. In sample No. 12, nitrogen gas, acetylene gas, and oxygen gas were introduced as reaction gases. Further, while the temperature of the base material was maintained at 500° C., the pressure of the reaction gas(es) was maintained at 6.0 Pa, and the voltage of a bias power supply was maintained at 50 V (DC power supply), an arc current of 150 A was supplied to each evaporation source for forming the coating layer. Thereby, metal ions were produced from each evaporation source for forming the coating layer, and the coating layer having a composition shown in Tables 1-1 and 1-2 was formed on a surface of the flank face in the base material (the second step: the step of forming the coating layer). Here, as each evaporation source for forming the coating layer, an evaporation source having a source material composition shown in Tables 1-1 and 1-2 was used. In addition, in samples Nos. 1 to 24, Ar gas was intermittently introduced at a partial pressure of 1 Pa, with an interval of more than or equal to 5 minutes and less than or equal to 30 minutes, during formation of the coating layer. On this occasion, a single supply of Ar gas was performed for 20 seconds. In samples Nos. 25 to 27, the intermittent introduction of Ar gas described above was not performed.

Through the above steps, cutting tools of samples Nos. 1 to 27 were fabricated.

TABLE 1-1

| | Film Formation Conditions for | | Coating Layer | | | | |
|---|---|---|---|---|---|---|---|
| | Coating Layer | | | Particle | | | |
| | | Intermittent | | Diameters of | Number of | Content | Thickness of |
| Sample | Source Material | Supply of | Composition of | Metal | Metal | Ratio of | Coating |
| No. | Composition | Ar Gas | Matrix Region | Particulates | Particulates* | Ar | Layer |
| 1 | Al_{0.55}Ti_{0.45} | performed | Al_{0.52}Ti_{0.48}N | 20 to 180 nm | 15 | 1 at % | 3 μm |
| 2 | Al_{0.6}Ti_{0.4} | performed | Al_{0.57}Ti_{0.43}N | 20 to 180 nm | 15 | 1 at % | 3 μm |
| 3 | Al_{0.7}Ti_{0.3} | performed | Al_{0.67}Ti_{0.33}N | 20 to 180 nm | 15 | 1 at % | 3 μm |
| 4 | Al_{0.63}Ti_{0.32}Cr_{0.05} | performed | Al_{0.6}Ti_{0.35}Cr_{0.05}N | 20 to 180 nm | 15 | 1 at % | 3 μm |
| 5 | Al_{0.63}Ti_{0.32}Si_{0.05} | performed | Al_{0.6}Ti_{0.35}Si_{0.05}N | 20 to 180 nm | 15 | 1 at % | 3 μm |
| 6 | Al_{0.63}Ti_{0.32}Nb_{0.05} | performed | Al_{0.6}Ti_{0.35}Nb_{0.05}N | 20 to 180 nm | 15 | 1 at % | 3 μm |
| 7 | Al_{0.63}Ti_{0.32}Ta_{0.05} | performed | Al_{0.6}Ti_{0.35}Ta_{0.05}N | 20 to 180 nm | 15 | 1 at % | 3 μm |
| 8 | Al_{0.63}Ti_{0.32}W_{0.05} | performed | Al_{0.6}Ti_{0.35}W_{0.05}N | 20 to 180 nm | 15 | 1 at % | 3 μm |
| 9 | Al_{0.63}Ti_{0.32}B_{0.05} | performed | Al_{0.6}Ti_{0.35}B_{0.05}N | 20 to 180 nm | 15 | 1 at % | 3 μm |
| 10 | Al_{0.63}Ti_{0.32}B_{0.05} | performed | Al_{0.6}Ti_{0.35}B_{0.05}C_{0.1}N_{0.9} | 20 to 180 nm | 15 | 1 at % | 3 μm |
| 11 | Al_{0.63}Ti_{0.32}B_{0.05} | performed | Al_{0.6}Ti_{0.35}B_{0.05}O_{0.1}N_{0.9} | 20 to 180 nm | 15 | 1 at % | 3 μm |
| 12 | Al_{0.63}Ti_{0.32}B_{0.05} | performed | Al_{0.6}Ti_{0.35}B_{0.05}C_{0.1}O_{0.1}N_{0.8} | 20 to 180 nm | 15 | 1 at % | 3 μm |
| 13 | Al_{0.63}Ti_{0.32}B_{0.05} | performed | Al_{0.6}Ti_{0.35}B_{0.05}N | 20 to 200 nm | 15 | 1 at % | 3 μm |
| 14 | Al_{0.63}Ti_{0.32}B_{0.05} | performed | Al_{0.6}Ti_{0.35}B_{0.05}N | 20 to 160 nm | 15 | 1 at % | 3 μm |
| 15 | Al_{0.63}Ti_{0.32}B_{0.05} | performed | Al_{0.6}Ti_{0.35}B_{0.05}N | 20 to 120 nm | 15 | 1 at % | 3 μm |

*the number in a field of view of 3 μm × 4 μm in a cross section of the coating layer

TABLE 1-2

| | Film Formation Conditions for | | Coating Layer | | | | |
|---|---|---|---|---|---|---|---|
| | Coating Layer | | | Particle | | | |
| | | Intermittent | | Diameters of | Number of | Content | Thickness |
| Sample | Source Material | Supply of | Composition of | Metal | Metal | Ratio of | of Coating |
| No. | Composition | Ar Gas | Matrix Region | Particulates | Particulates* | Ar | Layer |
| 16 | Al_{0.63}Ti_{0.32}B_{0.05} | performed | Al_{0.6}Ti_{0.35}B_{0.05}N | 20 to 180 nm | 12 | 1 at % | 3 μm |
| 17 | Al_{0.63}Ti_{0.32}B_{0.05} | performed | Al_{0.6}Ti_{0.35}B_{0.05}N | 20 to 180 nm | 24 | 1 at % | 3 μm |
| 18 | Al_{0.63}Ti_{0.32}B_{0.05} | performed | Al_{0.6}Ti_{0.35}B_{0.05}N | 20 to 180 nm | 36 | 1 at % | 3 μm |
| 19 | Al_{0.63}Ti_{0.32}B_{0.05} | performed | Al_{0.6}Ti_{0.35}B_{0.05}N | 20 to 180 nm | 15 | 2 at % | 3 μm |
| 20 | Al_{0.63}Ti_{0.32}B_{0.05} | performed | Al_{0.6}Ti_{0.35}B_{0.05}N | 20 to 180 nm | 15 | 3 at % | 3 μm |
| 21 | Al_{0.63}Ti_{0.32}B_{0.05} | performed | Al_{0.6}Ti_{0.35}B_{0.05}N | 20 to 180 nm | 15 | 1 at % | 2 μm |
| 22 | Al_{0.63}Ti_{0.32}B_{0.05} | performed | Al_{0.6}Ti_{0.35}B_{0.05}N | 20 to 180 nm | 15 | 1 at % | 8 μm |
| 23 | Al_{0.63}Ti_{0.32}B_{0.05} | performed | Al_{0.6}Ti_{0.35}B_{0.05}N | 20 to 180 nm | 15 | 1 at % | 12 μm |
| 24 | Al_{0.63}Ti_{0.32}B_{0.05} | performed | Al_{0.6}Ti_{0.35}B_{0.05}N | 20 to 180 nm | 15 | 1 at % | 20 μm |
| 25 | Al_{0.45}Ti_{0.55} | not performed | Al_{0.42}Ti_{0.58}N | 20 to 180 nm | 3 | 0 at % | 3 μm |
| 26 | Al_{0.6}Ti_{0.4} | not performed | Al_{0.57}Ti_{0.43}N | 20 to 180 nm | 3 | 0 at % | 3 μm |
| 27 | Al_{0.8}Ti_{0.2} | not performed | Al_{0.77}Ti_{0.23}N | 20 to 180 nm | 3 | 0 at % | 3 μm |

*the number in a field of view of 3 μm × 4 μm in a cross section of the coating layer

### Evaluation of Characteristics of Cutting Tools

Using the cutting tools of samples Nos. 1 to 27 fabricated as described above, characteristics of the cutting tools were evaluated as described below. It should be noted that the cutting tools of samples Nos. 1 to 24 correspond to examples, and the cutting tools of samples Nos. 25 to 27 correspond to comparative examples.

### Measurement of Thickness of Coating Film (Thickness of Coating Layer)

The thickness of each coating film (that is, the thickness of each coating layer) was determined by measuring thicknesses at 10 arbitrary points in a cross section sample parallel to a direction of a normal to the surface of the base material using a transmission electron microscope (TEM) (trade name: JEM-2100F, manufactured by JEOL Ltd.), and calculating an average value of the thicknesses measured at the 10 points. The observation magnification on this occasion was 10000 times. Tables 1-1 and 1-2 show the results.

### Matrix Region in Coating Layer

The composition of the matrix region in each coating layer was determined by analyzing the entire matrix region using TEM-accompanying energy dispersive X-ray spectroscopy (TEM-EDX). Specifically, first, each cutting tool was cut in a direction parallel to a direction of a normal to an interface of the coating layer, and a cut surface thereof was polished to fabricate a cut piece having a length of 2.5 mm, a width of 0.5 mm, and a thickness of 0.1 mm including the base material and the coating film. The cut piece was processed using an ion slicer apparatus (trade name: “IB-09060CIS”, manufactured by JEOL Ltd.) until the cut piece had a thickness of 50 nm or less, to obtain a measurement sample. Measurement was performed at each of 10 arbitrary points in a matrix region of the obtained measurement sample using TEM-EDX, to calculate the composition ratio of each constituent element. The observation magnification on this occasion was 20000 times. An average value of the composition ratios calculated at the 10 points for each constituent element was determined as the composition ratio of that constituent element in the matrix region. Here, the “10 arbitrary points” were selected from mutually different crystal grains in the matrix region. As an EDX apparatus, JED-2300 (trade name) manufactured by JEOL Ltd. was used. Tables 1-1 and 1-2 show the determined composition of each matrix region.

### Analysis of Ar in Coating Layer

The content ratio of Ar in the coating layer was determined by analyzing the entire matrix region of the measurement sample described above using TEM-EDX. Tables 1-1 and 1-2 show the results.

### Analysis of Metal Particulates in Coating Layer

(Particle Diameters of Metal Particulates)

Particle diameters of metal particulates in the coating layer were determined by the following method. First, each cutting tool was cut in the direction parallel to the direction of the normal to the interface of the coating layer, and a cut surface thereof was polished using a focused ion beam apparatus. Then, the polished cut surface was observed with the TEM to obtain an observation image (FIG. 4B). The observation magnification on this occasion was 100000 times. In the obtained observation image, the area of a cross section of each metal particulate was calculated. Then, the diameter of a circle having an area equal to the calculated area was calculated. The diameter of the circle calculated as describe above was defined as the particle diameter of the metal particulate. Tables 1-1 and 1-2 show the results.

(Number of Metal Particulates in One Field of View)

In addition, the number of the metal particulates in one field of view was counted using the observation image described above (FIG. 4A). The observation magnification on this occasion was 50000 times. On this occasion, the field of view was a field of view of 3 μm×4 μm in a cross section of the coating layer. Tables 1-1 and 1-2 show the results. It should be noted that a metal particulate which was partially out of the field of view for measurement was also counted as one metal particulate.

### Analysis of Fine Polycrystalline Structure in Coating Layer

The presence or absence of a fine polycrystalline structure in the coating layer was observed by analyzing an image of each cross section sample obtained with the TEM. Then, for a cross section sample in which a fine polycrystalline structure was observed, grain diameters of crystal grains constituting the fine polycrystalline structure were determined by the analysis using the electron beam diffraction method. Specifically, first, electron beam diffraction measurement was performed on a portion above the metal particulates in the cross section sample described above. On this occasion, the measurement was performed with the beam diameter of an emitted electron beam being changed from 2 nm to 30 nm. The beam diameter of the electron beam when the observed pattern changed from diffraction spots to a continuous ring pattern in an electron beam diffraction image was defined as the grain diameters of the crystal grains constituting the fine polycrystalline structure. Table 2 shows the results.

### Hardness and Young's Modulus of Coating Layer

The hardness and the Young's modulus of the coating layer in each cutting tool were measured by a nano-indentation method according to a standard procedure defined in “ISO 14577-1: 2015 Metallic materials-Instrumented indentation test for hardness and materials parameters-”. Here, the pushing depth was set to 100 nm. As a measurement apparatus, ENT-1100 (trade name) manufactured by Elionix Inc. was used. Table 2 shows the results.

### Cutting Test

### Turning Test

Using the cutting tools of samples Nos. 1 to 27 fabricated as described above, a cutting time taken until a wear amount (Vb wear amount) in the flank face of each cutting tool exceeded 0.2 mm under the following cutting conditions was measured. Table 2 shows the results. A cutting tool having a longer cutting time can be evaluated as a cutting tool that is more excellent in flank face wear resistance.

Cutting conditions

Workpiece: SCM435

Cutting speed: 120 m/min

Feeding amount: 0.1 mm/t

Cutting depth (ap): 0.8 mm, wet

TABLE 2

| | Fine Polycrystalline | | | |
|---|---|---|---|---|
| Sample | Structure (grain | Hardness | Young's | Cutting |
| No. | diameter: nm) | (GPa) | Modulus (GPa) | Test (m) |
| 1 | 20 | 36 | 450 | 20 |
| 2 | 20 | 35 | 440 | 24 |
| 3 | 20 | 34 | 430 | 22 |
| 4 | 20 | 37 | 460 | 24 |
| 5 | 20 | 38 | 480 | 24 |
| 6 | 20 | 39 | 490 | 24 |
| 7 | 20 | 39 | 490 | 24 |
| 8 | 20 | 39 | 490 | 24 |
| 9 | 20 | 37 | 460 | 24 |
| 10 | 20 | 38 | 480 | 26 |
| 11 | 20 | 38 | 480 | 26 |
| 12 | 20 | 38 | 480 | 26 |
| 13 | 25 | 37 | 460 | 24 |
| 14 | 15 | 39 | 490 | 26 |
| 15 | 8 | 40 | 500 | 28 |
| 16 | 20 | 37 | 460 | 24 |
| 17 | 20 | 37 | 460 | 24 |
| 18 | 20 | 37 | 460 | 24 |
| 19 | 20 | 37 | 460 | 24 |
| 20 | 20 | 37 | 460 | 24 |
| 21 | 20 | 37 | 460 | 20 |
| 22 | 20 | 37 | 460 | 24 |
| 23 | 20 | 37 | 460 | 22 |
| 24 | 20 | 37 | 460 | 20 |
| 25 | 20 | 32 | 460 | 7 |
| 26 | 20 | 32 | 460 | 7 |
| 27 | 20 | 22 | 320 | 6 |

Concerning the cutting test, based on the results in Table 2, the cutting tools of samples Nos. 1 to 24 had a good result such as a cutting time of 20 minutes or more. On the other hand, the cutting tools of samples Nos. 25 to 27 had a cutting time of less than 8 minutes. It has been found from the above results that the cutting tools of samples Nos. 1 to 24 were excellent in flank face wear resistance.

Although the embodiment and examples of the present invention have been described above, it is also originally intended to combine features of the embodiment and examples described above as appropriate.

It should be understood that the embodiment and examples disclosed herein are illustrative and non-restrictive in every respect. The scope of the present invention is defined by the scope of the claims, rather than the embodiment and examples described above, and is intended to include any modifications within the scope and meaning equivalent to the scope of the claims.

### REFERENCE SIGNS LIST

1a: rake face; 1b: flank face; 1c: cutting edge portion; 10: cutting tool; 11: base material; 12: coating layer; F: field of view for measurement.

1. A cutting tool comprising:
a base material including a flank face; and
a coating layer that coats the flank face,
the coating layer including a matrix region and metal particulates,
the matrix region being made of a compound represented by (AlₓTi_{y}X_{1-x-y})CᵥO_{w}N_{1-v-w}, where
x being more than 0.5 and less than or equal to 0.7,
y being more than or equal to 0.3 and less than 0.5,
1-x-y being more than or equal to 0 and less than or equal to 0.1,
v being more than or equal to 0 and less than or equal to 1,
w being more than or equal to 0 and less than or equal to 1,
1-v-w being more than or equal to 0 and less than or equal to 1,
X representing at least one element selected from the group consisting of chromium, silicon, niobium, tantalum, tungsten, and boron,
the metal particulates containing aluminum or titanium as a constituent element,
the metal particulates having particle diameters of more than or equal to 20 nm and less than or equal to 200 nm,
a number of the metal particulates being more than or equal to 12 and less than or equal to 36 in a field of view of 3 μm×4 μm in a cross section parallel to a direction of a normal to an interface of the coating layer.

2. The cutting tool according to claim 1, wherein
the coating layer further contains argon, and
the argon has a content ratio of more than 0 at % and less than or equal to 3 at % in the coating layer.

3. The cutting tool according to claim 1, wherein the X includes boron.

4. The cutting tool according to claim 1, wherein the coating layer has a thickness of more than or equal to 3 μm and less than or equal to 20 μm.
